(19) United States
(12) Patent Application Publication
(10) Pub. No.: US 2015/0255511 A1
(43) Pub. Date: Sep. 10, 2015

(54) NONVOLATILE MEMORY DEVICE

(71) Applicant: Kabushiki Kaisha Toshiba, Minato-ku (JP)

(72) Inventors: Takeshi TAKAGI, Yokkaichi (JP); Takeshi YAMAGUCHI, Yokkaichi (JP)

(73) Assignee: Kabushiki Kaisha Toshiba, Minato-ku (JP)

(21) Appl. No.: 14/454,929

(22) Filed: Aug. 8, 2014

Related U.S. Application Data
(60) Provisional application No. 61/950,432, filed on Mar. 10, 2014.

(51) Int. Cl. H01L 27/24; G11C 5/06; G11C 13/00

(52) U.S. Cl. CPC H01L 27/2463; G11C 13/0002; G11C 5/06; H01L 27/2436

(57) ABSTRACT

According to one embodiment, a plurality of first wirings are arranged along a first direction and a second direction that intersect each other and extending in a third direction perpendicular to the first and second directions. A plurality of second wirings extend in the second direction and are provided at predetermined intervals along the third direction of the first wirings. N channel field-effect transistors are provided at ends of the first wirings. Memory cells are placed at intersections of the first wirings and the second wirings. The memory cells are formed of a variable resistive layer of which the first wiring side is large in resistivity and the second wiring side is small in resistivity.

### CROSS-REFERENCE TO RELATED APPLICATIONS

This application is based upon and claims the benefit of priority from U.S. Provisional Application No. 61/950,432, filed on Mar. 10, 2014; the entire contents of which are incorporated herein by reference.

### FIELD

Embodiments described herein relate generally to a nonvolatile memory device.

### BACKGROUND

Resistive random access memory (hereinafter, referred to as ReRAM) in which a variable resistive layer capable of retaining a plurality of resistance states is used in a memory element is known. ReRAM having a three-dimensional structure in which nR-1Tr type strings in which a plurality of word lines are disposed on the side surfaces of bit lines, which are disposed perpendicular to a substrate and include select transistors at end portions thereof close to the substrate, in a height direction through variable resistive layers are disposed in the form of a matrix on the substrate has been proposed in the related art.

In the three-dimensional structured ReRAM, a bipolar type variable resistive layer which makes a memory element a high resistance state by a voltage pulse of one polarity and makes the memory element a low resistance state by a voltage pulse of the other polarity using voltage pulses of different polarities is used. Further, in recent years, there has been proposed a ReRAM whose variable resistive layer has a structure in which a first variable resistive layer and a second variable resistive layer of lower resistance than the first variable resistive layer are stacked.

However, in a conventional three-dimensional structured ReRAM, with the nR-1Tr type structure in which multiple word lines are arranged in a height direction along a side surface of a bit line having a select transistor via a variable resistive layer in between, multiple memory cells are connected to one bit line, and hence the suppression of interference between adjacent memory cells matters. It is desired to reliably form a filament in each memory cell so as to suppress interference between adjacent memory cells, but an optimum configuration of the variable resistive layer for that is not obvious.

Further, as to the variable resistive layer placed between a bit line and word lines, its directivity is not specified. Thus, when the structure is applied, as it is, to memory elements of a conventional three-dimensional structured ReRAM, an ReRAM stable in operation cannot be obtained.

### BRIEF DESCRIPTION OF THE DRAWINGS

FIG. 1 is a diagram showing an example of the main part of a nonvolatile memory device according to a first embodiment;

FIG. 2 is a diagram showing an example circuit diagram of a memory cell array;

FIG. 3 is a perspective view showing an example of the stacked structure of the memory cell array;

FIG. 4 is an example cross-sectional view along line A-A in FIG. 3;

FIG. 5 is an example top view of FIG. 3;

FIGS. 6A to 6D are diagrams for explaining the outline of the operation of the nonvolatile memory device according to the first embodiment;

FIG. 7 is a diagram showing an example of the structure of a memory cell array according to a second embodiment; and

FIGS. 8A to 8D are diagrams for explaining the outline of the operation of a nonvolatile memory device according to the second embodiment.

### DETAILED DESCRIPTION

According to one embodiment, a nonvolatile memory device has a plurality of first wirings, a plurality of second wirings, memory cells, and select transistors. The first wirings are arranged along a first direction and a second direction that intersect each other and extend in a third direction perpendicular to the first and second directions. The second wirings extend in the second direction and are provided at predetermined intervals along the third direction of the first wirings. The memory cells are placed at intersections of the first wirings and the second wirings, each of the memory cells being sandwiched between one of the first wirings and one of the second wirings. The select transistors are provided at ends of the first wirings. The select transistors are N channel field-effect transistors. The memory cells are formed of a variable resistive layer of which the resistance state changes according to an electrical signal applied thereto and of which the first wiring side is large in resistivity and the second wiring side is small in resistivity.

The nonvolatile memory devices according to embodiments will be described in detail below with reference to the accompanying drawings. The present invention is not limited to these embodiments. The cross-sectional views, top view, and perspective view of the nonvolatile memory device used in the embodiments below are schematic and may be different from actual things in relations between the thicknesses and widths of layers, ratios of the thicknesses of layers, and so on.

### First Embodiment

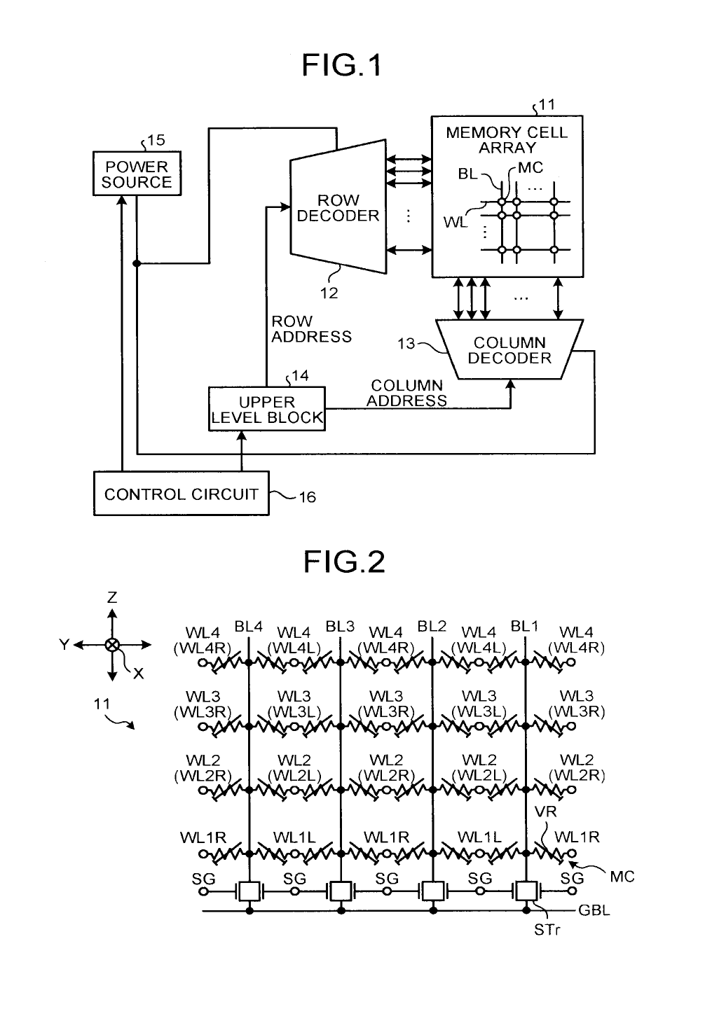

FIG. 1 is a diagram showing an example of the main part of a nonvolatile memory device according to the first embodiment. The nonvolatile memory device has a memory cell array 11, a row decoder 12, a column decoder 13, an upper level block 14, a power source 15, and a control circuit 16.

The memory cell array 11 has a plurality of word lines WL and bit lines BL that intersect each other, and memory cells MC placed at these intersections. The row decoder 12 selects a word line WL at the time of accessing (data erasing/writing/reading). The column decoder 13 selects bit lines BL at accessing and includes a driver that controls access operation.

The upper level block 14 selects memory cells MC to be accessed in the memory cell array 11. The upper level block 14 gives a row address and a column address to the row decoder 12 and column decoder 13 respectively. The power source 15 generates a combination of predetermined voltages corresponding to each operation of data erasing/writing/reading to supply to the row decoder 12 and column decoder 13. The control circuit 16 performs control such as sending an address to the upper level block 14 according to external commands and controls the power source 15.

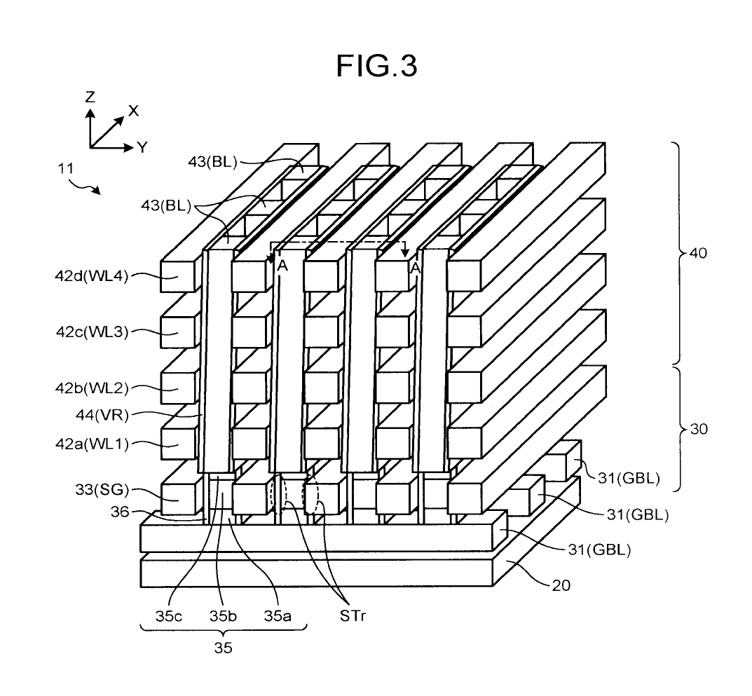

FIG. 2 is a diagram showing an example circuit diagram of the memory cell array, and FIG. 3 is a perspective view showing an example of the stacked structure of the memory cell array. In FIG. 2, the X direction, Y direction, and Z direction are orthogonal to each other, and the X direction is a direction perpendicular to the plane of the figure. The structure shown in FIG. 2 is repeatedly provided along the X direction.

The memory cell array 11 has select transistors STr, global bit lines GBL, and select gate lines SG as well as the aforementioned word lines WL, bit lines BL and memory cells MC as shown in FIG. 2.

The word lines WL1 to WL4 are arranged at predetermined pitches along the Z direction and extend in the X direction as shown in FIGS. 2 and 3. The bit lines BL are arranged in a matrix along the X and Y directions and extend in the Z direction. The memory cells MC are placed at the intersections of the word lines WL and the bit lines BL. Thus, the memory cells MC are arranged in a three-dimensional matrix along the X, Y, and Z directions. The memory cell MC includes a variable resistive element VR as shown in FIG. 2.

The select transistors STr are provided between one ends of the bit lines BL and the global bit line GBL as shown in FIG. 2. The global bit lines GBL are arranged at predetermined pitches along the X direction and extend in the Y direction. One global bit line GBL is connected in common to one ends of a plurality of select transistors STr arranged in a row along the Y direction.

The gate electrodes of two select transistors STr placed adjacent to each other in the Y direction can be connected in common. The select gate lines SG are arranged at predetermined pitches along the Y direction and extend in the X direction. One select gate line SG is connected in common to the gate electrodes of the plurality of select transistors STr arranged in a row along the X direction. Note that the gate electrodes of two select transistors STr placed adjacent to each other in the Y direction can also be separated for the two select transistors STr to operate independently of each other.

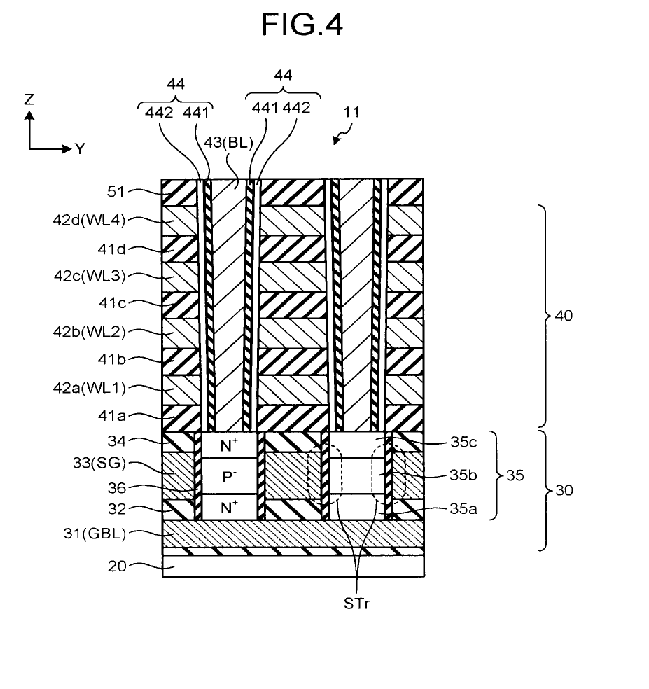

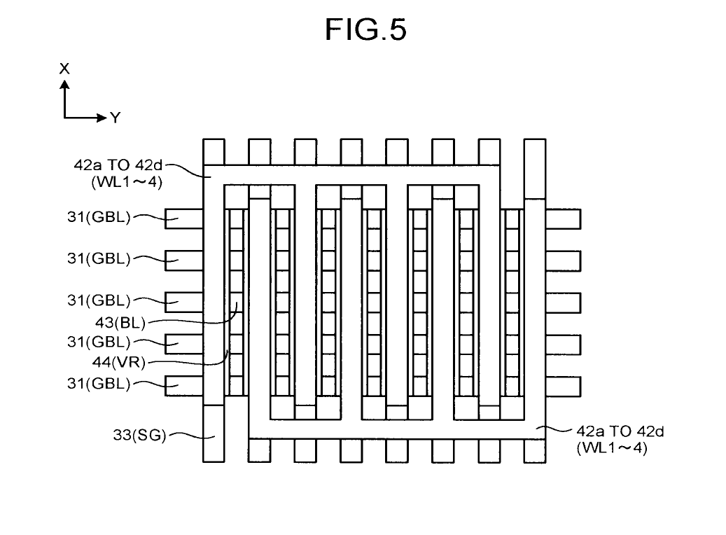

Next, the stacked structure of the memory cell array 11 according to the first embodiment will be described. FIG. 4 is an example cross-sectional view along line A-A in FIG. 3, and FIG. 5 is an example top view of FIG. 3. In FIGS. 3 and 5, interlayer insulating films are omitted from depiction.

The memory cell array 11 has a select transistor layer 30 and a memory layer 40 stacked above a substrate 20 as shown in FIGS. 3 and 4. The select transistor layer 30 functions as select transistors STr, and the memory layer 40 functions as memory cells MC.

The select transistor layer 30 has a conductive layer 31, an interlayer insulating film 32, a conductive layer 33, and an interlayer insulating film 34 as shown in FIGS. 3 and 4. The conductive layer 31, interlayer insulating film 32, conductive layer 33, and interlayer insulating film 34 are stacked along the Z direction perpendicular to the substrate 20. The conductive layer 31 functions as global bit lines GBL, and the conductive layer 33 functions as select gate lines SG and the gates of select transistors STr.

The conductive layer 31 has a strip shape extending in the Y direction, and a plurality of the conductive layers 31 are arranged at predetermined pitches along the X direction parallel to the substrate 20 (see FIG. 5). Interlayer insulating films, which are omitted from depiction in FIG. 3, are formed between the conductive layers 31.

The interlayer insulating film 32 is formed over the top of the conductive layer 31 and has a role of electrically insulating the conductive layer 31 and select gate lines SG (the conductive layer 33) from each other. The conductive layer 33 is formed in a strip shape extending in the X direction, and a plurality of the conductive layers 33 are arranged at predetermined pitches along the Y direction (see FIG. 5). The interlayer insulating film 34 is deposited to cover the side surfaces and upper surfaces of the conductive layers 33. The conductive layers 31, 33 are formed of, e.g., polysilicon. The interlayer insulating films 32, 34 are formed of silicon oxide (SiO₂).

Further, the select transistor layer 30 has a semiconductor layer 35 and a gate insulating layer 36 that are shaped like, e.g., a column as shown in FIGS. 3 and 4. The semiconductor layer 35 functions as the body (channel) of a select transistor STr, and the gate insulating layer 36 functions as the gate insulating film of the select transistor STr. Note that in the first embodiment, the select transistor layer 30 is constituted by an N channel field-effect transistor.

The semiconductor layers 35 are arranged in a matrix along the X and Y directions and extend in the Z direction. The semiconductor layer 35 touches the top of the conductive layer 31 and touches the side surface facing in the Y direction of a conductive layer 33 via the gate insulating layer 36. The semiconductor layer 35 has an N+ type semiconductor layer 35a, a P− type semiconductor layer 35b, and an N+ type semiconductor layer 35c stacked along the Z direction from bottom to top.

The N+ type semiconductor layer 35a touches, at the side surface facing in the Y direction, the interlayer insulating film 32 via the gate insulating layer 36 as shown in FIGS. 3 and 4. The P− type semiconductor layer 35b touches, at the side surface facing in the Y direction, a side surface of a conductive layer 33 via the gate insulating layer 36. The N+ type semiconductor layer 35c touches, at the side surface facing in the Y direction, the interlayer insulating film 34 via the gate insulating layer 36. The N+ type semiconductor layers 35a, 35c are formed of polysilicon having an N+ type impurity doped, and the P− type semiconductor layer 35b is formed of polysilicon having a P− type impurity doped. The gate insulating layer 36 is formed of, e.g., silicon oxide (SiO₂). Note that a barrier metal layer (omitted from depiction in FIG. 4) may be formed between the semiconductor layer 35 and the conductive layer 43 described later and between the semiconductor layer 35 and the conductive layer 31.

The memory layer 40 has interlayer insulating films 41a to 41d, 51 and conductive layers 42a to 42d, which are alternately stacked along the Z direction. The conductive layers 42a to 42d function as word lines WL1 to WL4 respectively. The conductive layers 42a to 42d each have a pair of comb-shaped portions facing each other in the X direction as seen in the Z direction (see FIG. 5). That is, word lines WLiR (i=1 to 4) belonging to one of a pair of comb-shaped portions of the conductive layer and word lines WLiL belonging to the other are alternately placed along the Y direction (see FIG. 2). By adopting this comb-shaped conductive layer, the number of contacts connected to the word line WL can be reduced. The interlayer insulating films 41a to 41d, 51 are formed of, e.g., silicon oxide (SiO₂), and the conductive layers 42a to 42d are formed of, e.g., W, Ti, WN, TiN, semiconductor material having conductivity such as p-type or n-type polysilicon, or so on.

The memory layer 40 has a plurality of column-shaped conductive layers 43 arranged along the X direction and variable resistive element forming layers 44 provided on opposite side surfaces in the Y direction of each conductive layer 43 to be shared, as shown in FIGS. 3 and 4. The conductive layers 43 function as bit lines BL. Of the variable resistive element forming layer 44, the areas sandwiched between the conductive layer 43 and the conductive layers 42a to 42d function as variable resistive elements VR.

The variable resistive element forming layer 44 is formed of a variable resistive material which can switch between a high resistance state and a low resistance state depending on the polarity (direction) of voltage applied thereto. A material containing metal oxide including at least one element of, e.g., Al, Ti, Hf, Zr, Nb, and Ta is used as the variable resistive material. Of the variable resistive element forming layer 44 according to the first embodiment, for the side opposite the conductive layer 43 that forms a local bit line, a material of large resistivity is used, and for the side opposite the conductive layers 42a to 42d that form word lines WL, a material of small resistivity is used. Specifically, it is desirable that the variable resistive element forming layer 44 is of a so-called two-layer structure of a first variable resistive layer 441 provided on the side opposite the conductive layer 43 that forms a local bit line and a second variable resistive layer 442 provided on the side opposite the conductive layers 42a to 42d that form word lines WL.

The first variable resistive layer 441 is constituted by an insulating film. For example, metal oxide such as silicon oxide or aluminum oxide, or metal nitride such as silicon nitride or aluminum nitride is used as the first variable resistive layer 441. The thickness of the first variable resistive layer 441 is desirably 3 nm or less. By setting the thickness of the first variable resistive layer 441 to be 3 nm or less, the distance between the local bit line (conductive layer 43) and the conductive layers 42a to 42d that form word lines WL can be shortened. As a result, the possibility that a filament may be formed also in an adjacent word line WL can be reduced, and thus a filament can be reliably formed for each word line WL.

The second variable resistive layer 442 is smaller in resistivity than the first variable resistive layer 441 and formed of metal oxide. A metal oxide including at least one element of, e.g., Al, Ti, Hf, Zr, Nb, and Ta is used as the second variable resistive layer 442. These metal oxides are lower in oxygen composition as compared with the stoichiometry proportion of these metal oxide materials.

The variable resistive element forming layer 44 goes into a low resistance state when a positive voltage larger than a first threshold voltage is applied thereto, and, in this state, when a negative voltage smaller than a second threshold voltage is applied thereto, goes into a high resistance state. When a voltage between the first threshold voltage and the second threshold voltage is applied, the resistance value does not change, but the low resistance state or high resistance state is maintained.

In another case, the variable resistive element forming layer 44 goes into the low resistance state when a negative voltage smaller than the first threshold voltage is applied thereto, and, in this state, when a positive voltage larger than the second threshold voltage is applied thereto, goes into the high resistance state. When a voltage between the first threshold voltage and the second threshold voltage is applied, the resistance value does not change, but the low resistance state or high resistance state is maintained.

As such, the variable resistive element forming layer 44 can be formed of a material that performs a so-called bipolar-type action. In the first embodiment, a forming operation makes a filament between the conductive layers 42a to 42d that form word lines WL and the conductive layer 43 that forms a local bit line, and a switch region, which performs a resistance varying action (switching action), is formed near the interface (first variable resistive layer 441) of the filament with the local bit line (conductive layer 43) side. In the switch region, switching between the high resistance state and the low resistance state is performed. In order to make this structure, the second variable resistive layer 442 is desirably formed to have a larger degree of oxygen deficiency than the first variable resistive layer 441, mainly in which the switch region is formed.

The band gap of the first variable resistive layer 441 is desirably larger than that of the second variable resistive layer 442. This is because when a positive voltage is applied to the word lines WL (conductive layers 42a to 42d) with respect to the bit line (conductive layer 43), a voltage is applied to the first variable resistive layer 441, thus facilitating the formation of the filament (switch region).

The conductive layers 43 are arranged in a matrix along the X and Y directions, and touch at the lower ends the top of the semiconductor layer 35 and extend in a column shape along the Z direction. Interlayer insulating films, which are omitted from depiction in FIG. 3, are formed between the semiconductor layers 43 arranged along the X direction.

The variable resistive element forming layer 44 is provided between a side surface in the Y direction of the conductive layer 43 and side surfaces in the Y direction of the interlayer insulating films 41a to 41d. Also, the variable resistive element forming layer 44 is provided between a side surface in the Y direction of the conductive layer 43 and side surfaces in the Y direction of the conductive layers 42a to 42d. In this variable resistive element forming layer, the first variable resistive layer 441 is placed on the side opposite the conductive layer 43 that forms a bit line BL, and the second variable resistive layer 442 is placed on the side opposite the conductive layers 42a to 42d that form word lines WL. The first variable resistive layer 441 is formed along the conductive layer 43 that forms a local bit line, opposite a side wall of the stacked structure of the conductive layers 42a to 42d and the interlayer insulating films 41a to 41d, 51. The conductive layer 43 is formed of, e.g., polysilicon.

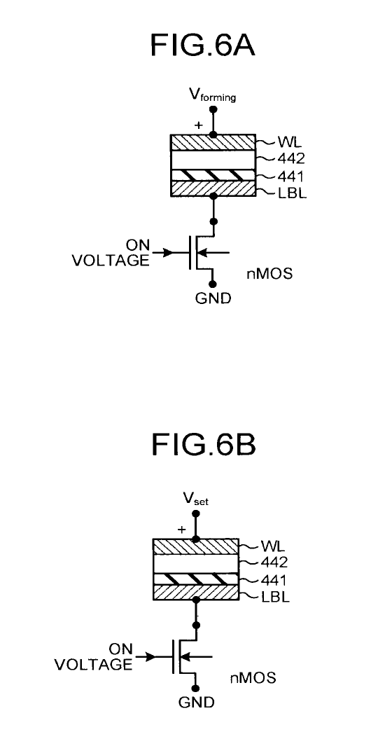

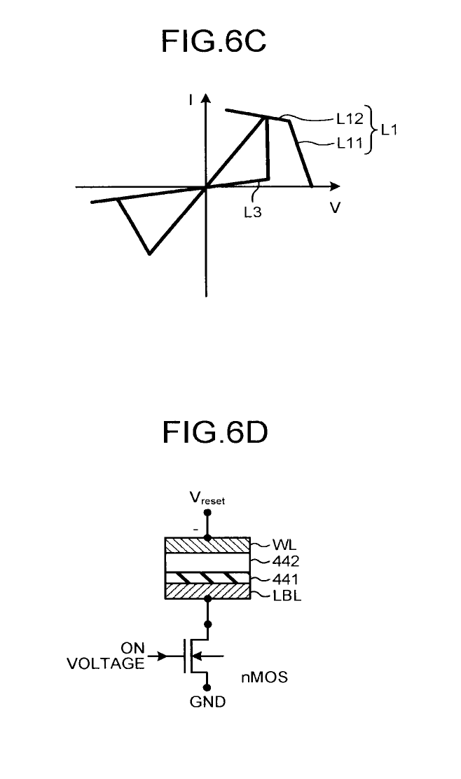

Next, forming operation, set operation, reset operation, and read operation in the nonvolatile memory device of this structure will be described briefly. FIGS. 6A to 6D are diagrams for explaining the outline of the operation of the nonvolatile memory device according to the first embodiment.

The variable resistive element forming layer 44 forming part of memory cells MC of the nonvolatile memory device immediately after being produced is in an insulator state, that is, the high resistance state. Accordingly, the forming operation is performed to form a filament in the variable resistive element forming layer 44. As shown in FIG. 6A, in the forming operation, the bit line BL connected to a selected memory cell MC is set at, e.g., ground potential GND, and a positive forming voltage Vforming is applied to the word line WL connected to the selected memory cell MC with respect to the bit line BL. Note that, for example, Vforming/2 is applied to the non-selected word lines WL. Further, an ON voltage is applied to the N channel select transistor of the local bit line LBL connected to the selected memory cell MC to put the select transistor in a conductive state. By this means, the filament is formed in the variable resistive element forming layer 44, and a switch region, mainly in which change in resistance occurs, is formed near the first variable resistive layer 441. As a result, the variable resistive element forming layer 44 goes into the low resistance state. Thereafter, the reset operation of changing the memory cell MC from the low resistance state to the high resistance state or the set operation of changing it from the high resistance state to the low resistance state is performed.

In performing the set operation of changing a selected memory cell MC from the high resistance state to the low resistance state as shown in FIG. 6B, the bit line BL connected to the selected memory cell MC is set at, e.g., ground potential GND, and a positive set voltage Vset is applied to the word line WL connected to the selected memory cell MC with respect to the bit line BL. Note that, for example, Vset/2 is applied to the non-selected word lines WL. Further, the ON voltage is applied to the N channel select transistor of the local bit line LBL connected to the selected memory cell MC to put the select transistor in the conductive state. By this means, oxygen ions O²⁻ are pushed away from the switch region of the selected memory cell MC toward the word line WL, so that a reduction reaction occurs in the switch region of the filament. It is supposedly a result of this that the switch region decreases in resistance, shifting to the low resistance state.

FIG. 6C is a graph showing a voltage vs. current characteristic of the memory cell and the load curve of the select transistor at the time of the setting. As shown an this figure, the load curve of the select transistor takes on L1. The load curve L1 in the first quadrant has a region L11 where the amount of flowing current greatly changes against the applied voltage and a region L12 where the amount of flowing current does not greatly change against the applied voltage. The load curve of the select transistor is one when the select transistor is on.

In performing the set operation on the memory cell MC, when a positive voltage is applied to the word line WL, at the set voltage Vset, a change from the high resistance state to the low resistance state occurs. At this time, the curve L3 indicating the voltage vs. current characteristic of the memory cell MC intersects with the region L12 of the load curve L1 of the select transistor, and the amount of current flowing at the time of the set operation is restricted by the select transistor. Because the curve L3 indicating the voltage vs. current characteristic of the memory cell MC intersects with the region L12 (a saturation region) of the load curve L1 of the select transistor, the operation with low current and less variation can be realized. The same is true of the forming operation.

In performing the reset operation of changing a selected memory cell MC from the low resistance state to the high resistance state as shown in FIG. 6D, the bit line BL connected to the selected memory cell MC is set at, e.g., ground potential GND, and a negative reset voltage Vreset is applied to the word line WL connected to the selected memory cell MC with respect to the bit line BL. Note that, for example, a voltage of Vreset/2, half of the reset voltage Vreset, is applied to the non-selected word lines WL. Further, the ON voltage is applied to the N channel select transistor of the local bit line LBL connected to the selected memory cell MC to put the select transistor in the conductive state. By this means, oxygen ions are attracted to the switch region of the selected memory cell MC, so that an oxidation reaction occurs in the switch region of the filament. It is supposedly a result of this that the switch region increases in resistance, shifting to the high resistance state.

In the read operation of reading out the state of a memory cell MC, a read voltage Vread is applied to the selected global bit line GBL for the local bit line LBL connected to the memory cell MC, and, e.g., 0V is applied to the non-selected global bit lines GBL. Further, for example, 0V is applied to the word line WL connected to the selected memory cell MC, whereas a voltage of Vread/2, half of the read voltage Vread, is applied to the non-selected word lines WL. Then, the select transistor STr connected to the local bit line LBL is selectively rendered conductive, with maintaining the other select transistors non-conductive. By this means, the read voltage Vread is applied to only the selected memory cell MC to perform read operation.

In the first embodiment, there is provided the nonvolatile memory device having a three-dimensional structure in which nR-1Tr type strings are vertically disposed above the substrate in a matrix; that is, the bit line is vertically disposed above the substrate and has the select transistor in the end portion on a side near the substrate, and the plurality of word lines are disposed on the side surface of the bit line in the height direction through the variable resistive element forming layer 44. The select transistor is constituted by an N channel field-effect transistor. The variable resistive element forming layer 44 has a bilayer structure in which the first variable resistive layer 441 of a large resistivity formed of an insulating film where a switch region to contribute to change in resistance is to be formed and the second variable resistive layer 442 of a small resistivity are stacked. The first variable resistive layer 441 is placed on the bit line side, and the second variable resistive layer 442 is placed on the word line side. By this means, the polarity dependency of the two-layer structure capable of stable low current operation and the directionality of current restriction by the saturation region of the select transistor at the set operation can be combined. As a result, current restriction can be stably performed at the forming operation or the set operation, and the three-dimensional nR-1Tr structure having the bilayer structure that operates stably can be provided. Further, at the set operation, drive operation with low current and less variation can be realized.

### Second Embodiment

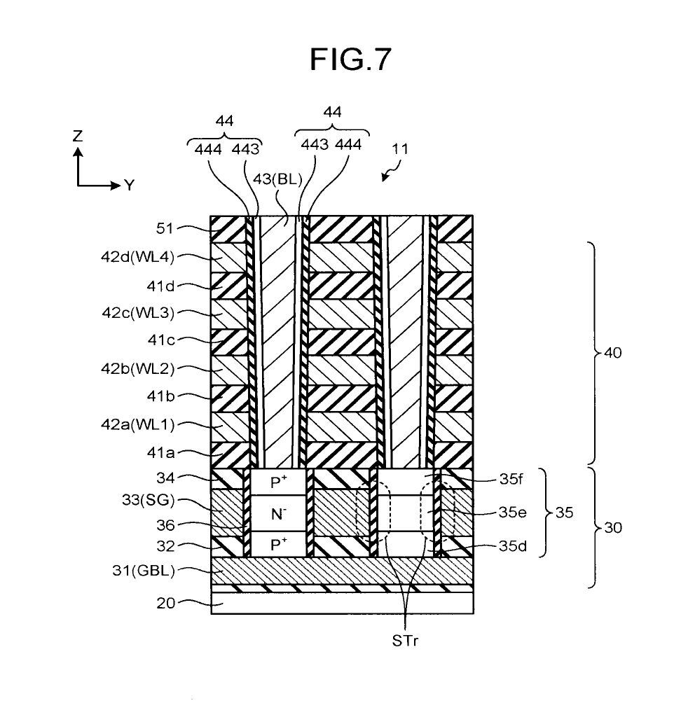

FIG. 7 is a diagram showing an example of the structure of a memory cell array according to the second embodiment and an example cross-sectional view along line A-A in FIG. 3. The memory cell array 11 has the same structure as the one described with reference to FIGS. 3 and 4 of the first embodiment. However, in the second embodiment, the select transistor is constituted by a P channel field-effect transistor. That is, the semiconductor layer 35 has a P+ type semiconductor layer 35d, an N− type semiconductor layer 35e, and a P+ type semiconductor layer 35f stacked along the Z direction from bottom to top.

The P+ type semiconductor layer 35d touches, at the side surface facing in the Y direction, the interlayer insulating film 32 via the gate insulating layer 36 as shown in FIGS. 3 and 7. The N− type semiconductor layer 35e touches, at the side surface facing in the Y direction, a side surface of a conductive layer 33 via the gate insulating layer 36. The P+ type semiconductor layer 35f touches, at the side surface facing in the Y direction, the interlayer insulating film 34 via the gate insulating layer 36. The P+ type semiconductor layers 35d, 35f are formed of polysilicon having a P+ type impurity doped, and the N− type semiconductor layer 35e is formed of polysilicon having an N− type impurity doped.

Of the variable resistive element forming layer 44 according to the second embodiment, for the side opposite the conductive layer 43 that forms a local bit line, a material of small resistivity is used, and for the side opposite the conductive layers 42a to 42d that form word lines WL, a material of large resistivity is used. Specifically, it is desirable that the variable resistive element forming layer 44 is of a bilayer structure of a first variable resistive layer 443 provided on the local bit line (conductive layer 43) side and a second variable resistive layer 444 provided on the word line WL (conductive layers 42a to 42d) side.

The first variable resistive layer 443 is lower in resistivity than the second variable resistive layer 444 and formed of metal oxide. A metal oxide including at least one element of, e.g., Al, Ti, Hf, Zr, Nb, and Ta is used as the first variable resistive layer 443. These metal oxides are lower in oxygen composition as compared with the stoichiometry proportion of these metal oxide materials.

The second variable resistive layer 444 is constituted by an insulating film. For example, metal oxide such as silicon oxide or aluminum oxide, or metal nitride such as silicon nitride or aluminum nitride is used as the second variable resistive layer 444. The thickness of the second variable resistive layer 444 is desirably 3 nm or less. By setting the thickness of the second variable resistive layer 444 to be 3 nm or less, the distance between the conductive layer 43 that forms the local bit line and the conductive layers 42a to 42d that form word lines WL can be shortened. As a result, the possibility that a filament may be formed also in an adjacent word line WL can be reduced, and thus a filament can be reliably formed for each word line WL.

The variable resistive element forming layer 44 goes into a high resistance state when a positive voltage larger than a first threshold voltage is applied thereto, and, in this state, when a negative voltage smaller than a second threshold voltage is applied thereto, goes into a low resistance state. When a voltage between the first threshold voltage and the second threshold voltage is applied, the resistance value does not change, but the low resistance state or high resistance state is maintained.

In another case, the variable resistive element forming layer 44 goes into the high resistance state when a negative voltage smaller than the first threshold voltage is applied thereto, and, in this state, when a positive voltage larger than the second threshold voltage is applied thereto, goes into the low resistance state. When a voltage between the first threshold voltage and the second threshold voltage is applied, the resistance value does not change, but the low resistance state or high resistance state is maintained.

As such, the variable resistive element forming layer 44 can be formed of a material that performs a so-called bipolar-type action. In the second embodiment, a forming operation makes a filament between the conductive layers 42a to 42d that form word lines WL and the conductive layer 43 that forms a local bit line, and a switch region, which performs a resistance varying action (switching action), is formed near the interface (second variable resistive layer 444) of the filament with the word line WL (conductive layers 42a to 42d) side. In the switch region, switching between the high resistance state and the low resistance state is performed. In order to make this structure, the first variable resistive layer 443 is desirably formed to have a larger degree of oxygen deficiency than the second variable resistive layer 444, mainly in which the switch region is formed.

The band gap of the second variable resistive layer 444 is desirably larger than that of the first variable resistive layer 443. This is because when a negative voltage is applied to the word lines WL (conductive layers 42a to 42d) with respect to the bit line (conductive layer 43), a voltage is applied to the second variable resistive layer 444, thus facilitating the formation of the filament. The same reference numerals are used to denote the same constituents as in the first embodiment with description thereof being omitted.

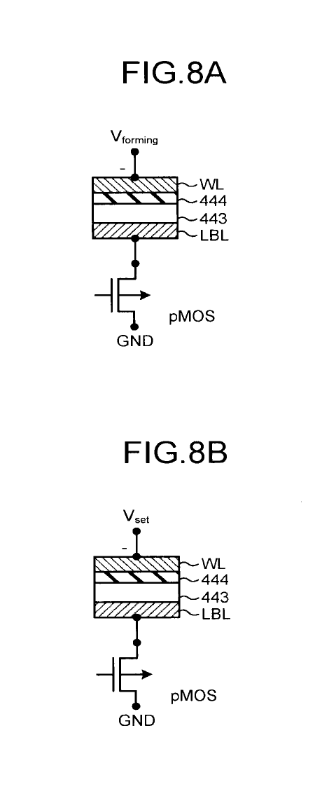

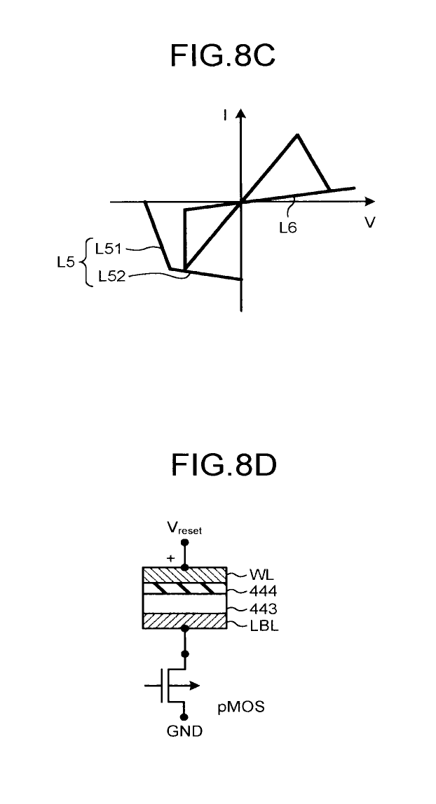

Next, forming operation, set operation, reset operation, and read operation in the nonvolatile memory device of this structure will be described briefly. FIGS. 8A to 8D are diagrams for explaining the outline of the operation of a nonvolatile memory device according to the second embodiment.

The variable resistive element forming layer 44 forming part of memory cells MC of the nonvolatile memory device immediately after being produced is in an insulator state, that is, the high resistance state. Accordingly, the forming operation is performed to form a filament in the variable resistive element forming layer 44. As shown in FIG. 8A, in the forming operation, the bit line BL connected to a selected memory cell MC is set at, e.g., ground potential GND, and a negative forming voltage Vforming is applied to the word line WL connected to the selected memory cell MC with respect to the bit line BL. Note that, for example, Vforming/2 is applied to the non-selected word lines WL. Further, an ON voltage is applied to the P channel select transistor of the local bit line LBL connected to the selected memory cell MC to put the select transistor in a conductive state. As a result, the filament is formed in the variable resistive element forming layer 44, and a switch region, mainly in which change in resistance occurs, is formed near the second variable resistive layer 444. Thus, the variable resistive element forming layer 44 goes into the low resistance state. Thereafter, the reset operation of changing the memory cell MC from the low resistance state to the high resistance state or the set operation of changing it from the high resistance state to the low resistance state is performed.

In performing the set operation of changing a selected memory cell MC from the high resistance state to the low resistance state as shown in FIG. 8B, the bit line BL connected to the selected memory cell MC is set at, e.g., ground potential GND, and a negative set voltage Vset is applied to the word line WL connected to the selected memory cell MC with respect to the bit line BL. Note that, for example, Vset/2 is applied to the non-selected word lines WL. Further, the ON voltage is applied to the P channel select transistor of the local bit line LBL connected to the selected memory cell MC to put the select transistor in the conductive state. By this means, oxygen ions O²⁻ are pushed away from the switch region of the selected memory cell MC toward the bit line BL side, so that a reduction reaction occurs in the switch region of the filament. It is supposedly a result of this that the switch region decreases in resistance, shifting to the low resistance state.

FIG. 8C is a graph showing a voltage vs. current characteristic of the memory cell and the load curve of the select transistor at the time of the setting. As shown in this figure, the load curve of the select transistor takes on L5 in the third quadrant. The load curve L5 in the third quadrant has a region L51 where the amount of flowing current greatly changes against the applied voltage and a region L52 (a saturation region) where the amount of flowing current does not greatly change against the applied voltage. The load curve of the select transistor is one when the select transistor is on.

In performing the set operation on the memory cell MC, when a negative voltage is applied to the word line WL, at the set voltage Vset, a change from the high resistance state to the low resistance state occurs. At this time, the curve L6 indicating the voltage vs. current characteristic of the memory cell MC intersects with the region L52 of the load curve L5 of the select transistor, and the amount of current flowing at the time of the set operation is restricted by the select transistor. Because the curve indicating the voltage vs. current characteristic of the memory cell MC intersects with the region L52 (a saturation region) of the load curve L5 of the select transistor, the operation with low current and less variation can be realized. The same is true of the forming operation.

In performing the reset operation of changing a selected memory cell MC from the low resistance state to the high resistance state as shown in FIG. 8D, the bit line BL connected to the selected memory cell MC is set at, e.g., ground potential GND, and a positive reset voltage Vreset is applied to the word line WL connected to the selected memory cell MC with respect to the bit line BL. Note that, for example, a voltage of Vreset/2, half of the reset voltage Vreset, is applied to the non-selected word lines WL. Further, the ON voltage is applied to the P channel select transistor of the local bit line LBL connected to the selected memory cell MC to put the select transistor in the conductive state. By this means, oxygen ions O²⁻ are attracted to the switch region of the selected memory cell MC, so that an oxidation reaction occurs in the switch region of the filament. It is supposedly a result of this that the switch region increases in resistance, shifting to the high resistance state.

In the read operation of reading out the state of a memory cell MC, a read voltage Vread is applied to the selected global bit line GBL for the local bit line LBL connected to the memory cell MC, and, e.g., 0V is applied to the non-selected global bit lines GBL. Further, for example, 0V is applied to the word line WL connected to the selected memory cell MC, whereas a voltage of Vread/2, half of the read voltage Vread, is applied to the non-selected word lines WL. Then, the select transistor STr connected to the local bit line LBL is selectively rendered conductive, with maintaining the other select transistors non-conductive. By this means, the read voltage Vread is applied to only the selected memory cell MC to perform read operation.

In the second embodiment, there is provided the nonvolatile memory device having a three-dimensional structure in which nR-1Tr type strings are vertically disposed above the substrate in a matrix; that is, the bit line is vertically disposed above the substrate and has the select transistor in the end portion on a side near the substrate, and the plurality of word lines are disposed on the side surface of the bit line in the height direction through the variable resistive element forming layer 44. The select transistor is constituted by a P channel field-effect transistor. The variable resistive element forming layer 44 has a bilayer structure in which the first variable resistive layer 443 of a small resistivity and the second variable resistive layer 444 of a large resistivity formed of an insulating film where a switch region to contribute to change in resistance is to be formed are stacked. As such, by inserting the insulating film (second variable resistive layer 444), the possibility that a filament may be formed also in an adjacent word line WL can be reduced, and thus the embodiment has the effect that a filament can be reliably formed for each word line WL.

The first variable resistive layer 443 is placed on the bit line side, and the second variable resistive layer 444 is placed on the word line side. By this means, the polarity dependency of the bilayer structure capable of stable low current operation and the directionality of current restriction by the saturation region of the select transistor at the set operation can be combined. As a result, current restriction can be stably performed at the forming operation or the set operation, and the three-dimensional nR-1Tr structure having the bilayer structure that operates stably can be provided. Further, at the set operation, drive operation with low current and less variation can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile memory device comprising:
a plurality of first wirings arranged along a first direction and a second direction that intersect each other and extending in a third direction perpendicular to the first and second directions;
a plurality of second wirings extending in the second direction and provided at predetermined intervals along the third direction of the first wirings;
memory cells placed at intersections of the first wirings and the second wirings, each of the memory cells being sandwiched between one of the first wirings and one of the second wirings; and
select transistors provided at ends of the first wirings,
wherein the select transistors are N channel field-effect transistors, and
the memory cells are formed of a variable resistive layer of which the resistance state changes according to an electrical signal applied thereto and of which the first wiring side is large in resistivity and the second wiring side is small in resistivity.

2. The nonvolatile memory device according to claim 1, wherein the variable resistive layer is formed of a material whose resistance value reversibly changes based on an electrical signal applied across the first wiring and the second wiring that takes on different polarities.

3. The nonvolatile memory device according to claim 2, further comprising a controller,
wherein the controller can apply a positive forming voltage to the second wiring with respect to the first wiring at the time of forming operation of forming a filament in the variable resistive layer.

4. The nonvolatile memory device according to claim 1, wherein the variable resistive layer has a two-layer structure formed of a first layer placed on the first wiring side and a second layer placed on the second wiring side and having a larger degree of oxygen deficiency than the first layer.

5. The nonvolatile memory device according to claim 1, wherein the band gap of the first layer is larger than the band gap of the second layer.

6. The nonvolatile memory device according to claim 5, wherein interlayer insulating films are placed between adjacent ones in the third direction of the second wirings, and
the variable resistive layer is provided on a side surface in the first direction of a stacked structure of the second wirings and the interlayer insulating films.

7. The nonvolatile memory device according to claim 5, wherein the first layer has a thickness of 3 nm or less.

8. A nonvolatile memory device comprising:
a plurality of first wirings arranged along a first direction and a second direction that intersect each other and extending in a third direction perpendicular to the first and second directions;
a plurality of second wirings extending in the second direction and provided at predetermined intervals along the third direction of the first wirings;
memory cells placed at intersections of the first wirings and the second wirings, each of the memory cells being sandwiched between one of the first wirings and one of the second wirings; and
select transistors provided at ends of the first wirings,
wherein the select transistors are P channel field-effect transistors, and
the memory cells are formed of a variable resistive layer of which the resistance state changes according to an electrical signal applied thereto and of which the first wiring side is small in resistivity and the second wiring side is large in resistivity.

9. The nonvolatile memory device according to claim 8, wherein the variable resistive layer is formed of a material whose resistance value reversibly changes based on an electrical signal applied across the first wiring and the second wiring that takes on different polarities.

10. The nonvolatile memory device according to claim 9, further comprising a controller,
wherein the controller can apply a negative forming voltage to the second wiring with respect to the first wiring at the time of forming operation of forming a filament in the variable resistive layer.

11. The nonvolatile memory device according to claim 8, wherein the variable resistive layer has a two-layer structure formed of a first layer placed on the first wiring side and a second layer placed on the second wiring side and having a smaller degree of oxygen deficiency than the first layer.

12. The nonvolatile memory device according to claim 8, wherein the band gap of the second layer is larger than the band gap of the first layer.

13. The nonvolatile memory device according to claim 12, wherein interlayer insulating films are placed between adjacent ones in the third direction of the second wirings, and
the variable resistive layer is provided on a side surface in the first direction of a stacked structure of the second wirings and the interlayer insulating films.

14. The nonvolatile memory device according to claim 12, wherein the second layer has a thickness of 3 nm or less.
